(19) United States
(12) Patent Application Publication
(10) Pub. No.: US 2022/0238823 A1
(43) Pub. Date: Jul. 28, 2022

(54) ELECTRONIC RATCHET

(71) Applicant: Alliance for Sustainable Energy, LLC, Golden, CO (US)

(72) Inventors: Andrew John FERGUSON, Louisville, CO (US); Jeffrey Lee BLACKBURN, Golden, CO (US); Ji HAO, Santa Clara, CA (US)

(21) Appl. No.: 17/613,621

(22) PCT Filed: May 22, 2020
(86) PCT No.: PCT/US20/34382

§ 371 Date: Nov. 23, 2021

Related U.S. Application Data
(60) Provisional application No. 62/852,696, filed on May 24, 2019.
(60) Provisional application No. 62/852,747, filed on May 24, 2019.

(51) Int. Cl. H01L 51/05; H01L 51/10

(52) U.S. Cl. CPC H01L 51/0566; H01L 51/0525; H01L 51/105; H01L 51/0545; H01L 51/055

(57) ABSTRACT

Electronic ratchet devices comprising a pair of first and second electrodes; a dielectric layer; a gate electrode layer; and a transport layer are disclosed herein.

### CROSS-REFERENCE TO RELATED APPLICATIONS

This application claim priority under 35 U.S.C. § 371 to PCT Patent Application No. PCT/US2020/034382 filed on 22 May 2020 which claims priority under 35 U.S.C. § 119 to U.S. Provisional Patent Application Nos. 62/852,696 and 62/852,747 both of which were filed on 24 May 2019, all of the contents of which are hereby incorporated in their entirety.

### CONTRACTUAL ORIGIN

The United States Government has rights in this invention under Contract No. DE-AC36-08GO28308 between the United States Department of Energy and the Alliance for Sustainable Energy, LLC., the Manager and Operator of the National Renewable Energy Laboratory.

### BACKGROUND

In the past decade, Moore's Law has fostered the evolution of electronic devices and controls that are increasingly smaller, lighter, and more portable. While this evolution has the potential to revolutionize our daily lives in an increasingly “wireless” economy, it also places new demands on the way in which we power the next generation of wireless devices. For many ultra-light and/or compact wireless devices, batteries can significantly increase the device weight and footprint, negating the intended benefits of these portable electronics and increasing the maintenance costs (battery replacement) and environmental consequences (battery waste disposal). Additionally, distributed sensors and switches are seen as a viable path towards intelligent energy load management in buildings, with a predicted 30% reduction in energy used by HVAC systems in both residential and commercial buildings that could result in up to a ca. 4% reduction in annual energy consumption in the U.S. The low powers needed to drive these sensors and switches are well matched to simple, light-weight power supplies that can harvest small, but reliable, sources of ambient energy.

Electronic ratchets are devices capable of rectifying randomly oscillating (stochastic) voltages, such as those due to thermal noise, represent a potential power delivery solution in such wireless applications. Most experimental demonstrations of electronic ratchets have been limited to complex, lithographically-patterned, quantum-confined features in heterostructures of III-V semiconductors at cryogenic temperatures. However, in the last 6 years, electronic ratchets operating at room temperature have been demonstrated that employ fairly simple device architectures (based on a field-effect transistor geometry) and use organic semiconductors. However, their performance is limited by the charge carrier density and mobility (typically far less than 1 cm² V⁻¹ s⁻¹).

Electronic ratchets are energy-harvesting devices that can utilize spatially asymmetric potential distributions to convert nondirectional/Random sources of energy into direct current. The potential asymmetry can be generated in a number of ways, but one purported mechanism is to redistribute ions directly within the active material. Utilizing the known propensity for ion migration in lead-halide perovskites, we demonstrate the first perovskite electronic ratchet by using a voltage stress to intentionally redistribute halide ions within a prototypical two-dimensional perovskite. The resulting asymmetric potential distribution across the 2D perovskite can convert both electronic noise and unbiased square-wave potentials into stable current. Furthermore, simultaneous application of light illumination and voltage stress enhances the asymmetric potential distribution, enabling higher current than a biased device. This work presents a new type of electronic ratchet which can be modified by both electrical and optical stimuli, and also provides a model system which can potentially test many outstanding mechanistic questions for electronic ratchets.

‘Ratchet’ systems are systems out of thermal equilibrium that also possess spatial inversion asymmetry, whereby external stimuli can induce directed transport (e.g. of ions, molecules, or charge carriers). Electronic ratchets are structurally or electronically asymmetric devices that can rectify electromagnetic noise or unbiased alternating current (AC) signals to yield useful direct current (DC) and power. Recently, several simple electronic ratchet concepts, based on a field-effect transistor (FET) architecture, have been demonstrated for organic semiconductors, whereby the asymmetry needed to ratchet charge carriers can be produced directly in the material by (ostensibly) driving ion motion, provided through the choice of electrode work function, through the use of periodic, patterned electrode pairs, or through a light-assisted patterned device. The ability for such devices to harvest electromagnetic noise suggests they could potentially provide the energy needed for low-power, portable applications where electrical grid access and/or charging batteries may be impractical.

In the most popular incarnation of the organic electronic ratchet, asymmetric potential distribution is developed directly within the material by applying a voltage stress. While this effect is purported to arise from the electric field-induced redistribution of ions, direct evidence for ion movement is rarely observed and it is often unclear what ions would be mobile in these systems (especially when not intentionally doped). The exploitation of ion motion in “soft” materials suggests that hybrid organic-inorganic lead-halide perovskites, where ion motion is known to be relatively facile represent potential alternative semiconductor materials for electronic ratchet devices. While lead-halide perovskite semiconductors have emerged as revolutionary materials for high-efficiency electronic and optoelectronic applications, ion/vacancy migration and accumulation often contribute to device degradation. Despite these potentially deleterious effects, several recent studies suggest that intentional manipulation of ions by external stimuli (e.g. electric field and/or light illumination) can also afford new types of opto-electronic devices.

### SUMMARY

In an aspect, disclosed herein is an electronic ratchet device comprising a pair of first and second electrodes; a dielectric layer; a gate electrode layer; and a transport layer. In an embodiment, the electronic ratchet device has a transport layer that connects the first and second electrodes, and the dielectric layer separates the transport layer and the gate electrode layer. In an embodiment, the electronic ratchet device has first and second electrodes that comprise a pair of electrodes and wherein both the first and the second electrode are fabricated from the same metal. In an embodiment, the electronic ratchet device has first and second electrodes that are fabricated from metal with dissimilar work functions. In another embodiment, the electronic ratchet device has first and second electrodes that are fabricated from metal selected from the group consisting of gold, silver, and aluminum. In an embodiment, the electronic ratchet device has a dielectric layer that comprises an insulating layer with high capacitance. In another embodiment, the electronic ratchet device has a dielectric layer that comprises an insulating layer selected from the group consisting of silicon dioxide, hafnium dioxide, and zirconium dioxide. In an embodiment, the electronic ratchet device has a gate electrode that comprises a conductive layer. In another embodiment, the electronic ratchet device has a gate electrode that comprises highly-doped silicon. In an embodiment, the electronic ratchet device has a transport layer that comprises a semiconductor film. In an embodiment, the electronic ratchet device comprises a network of enriched semiconducting perovskite. In an embodiment, the electronic ratchet device has a semiconductor film that comprises nanocrystal CsPbI₃. In an embodiment, the electronic ratchet device has a semiconductor film that comprises 2D layered perovskite C₇H₁₀N.

In another embodiment, the electronic ratchet device has a semiconductor film that comprises a network of enriched semiconducting single-walled carbon nanotubes. In an embodiment, the electronic ratchet device has an I_{Sc} of greater than about 2.88 mA. In another embodiment, the electronic ratchet device has a V_{oc} of greater than about 19 V. In another embodiment, the electronic ratchet device is capable of generating power of greater than about 2.24×10⁻² W. In another embodiment, the electronic ratchet device has an I_{Sc} of greater than about 2.88 mA, a V_{oc} of greater than about 19 V, and is capable of generating power of greater than about 2.24×10⁻² W.

In an aspect, disclosed herein is a method for making the electronic ratchet device.

In another aspect, disclosed herein is a system for generating power that uses electronic ratchet devices.

In an aspect, disclosed herein is a method for making power comprising exposing electronic ratchet devices to radiation.

### BRIEF DESCRIPTION OF THE DRAWINGS

FIG. 1 depicts a compact energy harvesting device based on conversion of time-varying (but zero time-average) input voltages by a carbon nanotube electronic ratchet based on a transistor geometry.

FIG. 2 depicts the net current flow in an asymmetrically doped SWCNT electronic ratchet, driven by time-varying potentials applied directly to the gate electrode.

FIG. 3 depicts net current flow in SWCNT electronic ratchet, driven by periodic potentials applied to asymmetric interdigitated electrodes (AF1/AF2).

FIGS. 4a-4f depict (a) Schematic of undoped s-SWCNT electronic ratchet device; (b) Current-Voltage (I-V) curves before (black) and after (red) voltage stress, and under application of AC square waveform bias signal to the gate contact for the voltage-stressed device (blue). (c) Ratchet current response when a random noise bias signal is applied to the gate electrode. (d, e, f) Variation of short-circuit current (I_{SC}), open-circuit voltage (V_{OC}) and maximum power of the s-SWCNT device on the frequency of the AC square waveform (Vₐ=5V).

FIGS. 5a-5e depict scanning Kelvin probe microscopy (SKPM) measurements of the potential distribution for V_{d}=±5V before and after voltage stress of undoped s-SWCNT electronic ratchet. (a) Topographical height profile between the source (S) and drain (D); (b, d) Surface potential line scans before (black dashed) and after (solid red) voltage stress, for V_{d}=−5V and V_{d}=+5V, separately, between source (S) and drain (D) terminals; (c) Differential resistance line before (black dashed) and after (solid red) voltage stress at V_{d}=−5V; (e) Differential resistance line before (black dashed) and after (solid red) voltage stress, V_{d}=±5V.

FIGS. 6a-6f depict (a) Schematic of p-type doped (using triethyloxonium hexachloroantimonate, OA) s-SWCNT electronic ratchet device; (b) Current-Voltage (I-V) curves before (black) and after (red) voltage stress, and under application of AC square waveform bias signal to the gate contact for the voltage-stressed device (blue). (c) Ratchet current response when a random noise bias signal is applied to the gate electrode. (d, e, f) Variation of short-circuit current (I_{SC}), open-circuit voltage (V_{OC}) and maximum power of the s-SWCNT device on the frequency of the AC square waveform (Vₐ=5V).

FIGS. 7a-7f depict (a) Schematic of n-type doped (using benzyl viologen, BV) s-SWCNT electronic ratchet device; (b) Transistor transfer curves. (c) Source-drain current-voltage curves after voltage stress (red) and under application of AC square waveform bias signal to the gate contact for the voltage-stressed device (red). (d, e, f) Variation of short-circuit current (I_{SC}), open-circuit voltage (V_{OC}) and maximum power of the s-SWCNT device on the frequency of the AC square waveform (Vₐ=5V).

FIGS. 8a-8f depict (a) Schematic of the partially p-type doped s-SWCNT electronic ratchet device, to generate a built-in asymmetric doping junction profile; (b) Current-Voltage (I-V) curves (black), and under application of AC square waveform bias signal to the gate contact for the SWCNT device (red). (c) Ratchet current response when a random noise bias signal is applied to the gate electrode. (d, e, f) Variation of short-circuit current (I_{SC}), open-circuit voltage (V_{OC}) and maximum power of the s-SWCNT device on the frequency of the AC square waveform (Vₐ=5V).

FIGS. 9a-9b depict a built-in junction characterized by a Confocal Raman microscopy system. (a) Variation of Intensity ratios between D band and G band (I_{D}/I_{G}) depend on the concentrations of OA solutions, there is an apparent step between the undoped and doped area. (b) Dependence of intensity ratios between G′ band and G band (I_{G′}/I_{G}) on the concentrations of OA solutions, a clear step is shown between the undoped and doped area. The step jump between the undoped and doped area clearly demonstrates there is doping profile built in the s-SWCNT channel.

FIG. 10 depicts an embodiment of a SWCNT electronic ratchet.

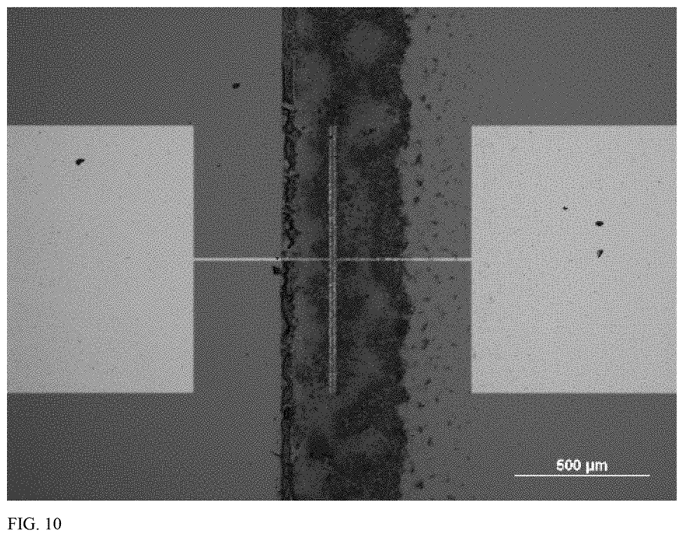

FIGS. 11a-11c depict the characterization of SWCNT network having a high purity of semiconducting SWCNTs with very low defects and having a carrier mobility of from about 20 to about 50 cm² V⁻¹ S⁻¹ by 11(a) UV-vis-NIR spectroscopy, 11(b) Raman spectroscopy, and 11(c) a field effect transistor measurement.

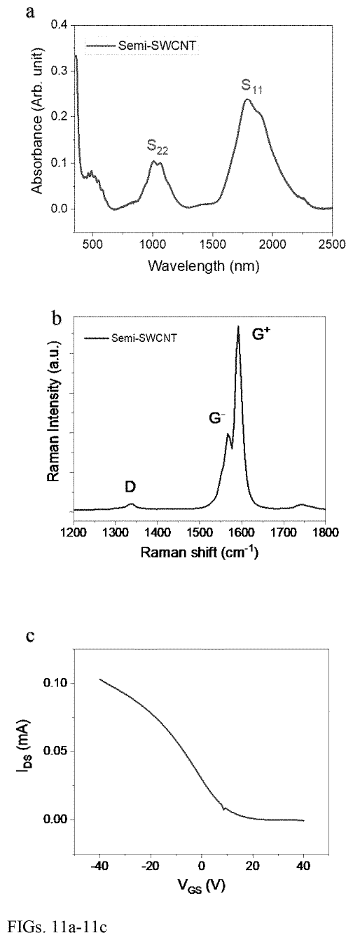

FIGS. 12a-12c depict the characterization of (12(a) and 12(b) an exemplary SWCNT electronic ratchet device having an I_{sc} of 2.88 mA, a V_{oc} of 19 V and power of 2.24×10⁻² W as compared to an exemplary organic electronic ratchet device having a an I_{sc} of 0.0967 mA, a V_{oc} of 8.65 V and power of 1.69×10⁻⁴ W. FIG. 12 c depicts the power versus frequency response of the exemplary SWCNT electronic ratchet device further characterized in FIG. 12a. As depicted in FIGS. 12a-12c, the energy transfer ability of the SWCNT electronic ratchet is better than currently available organic electronic ratchet devices.

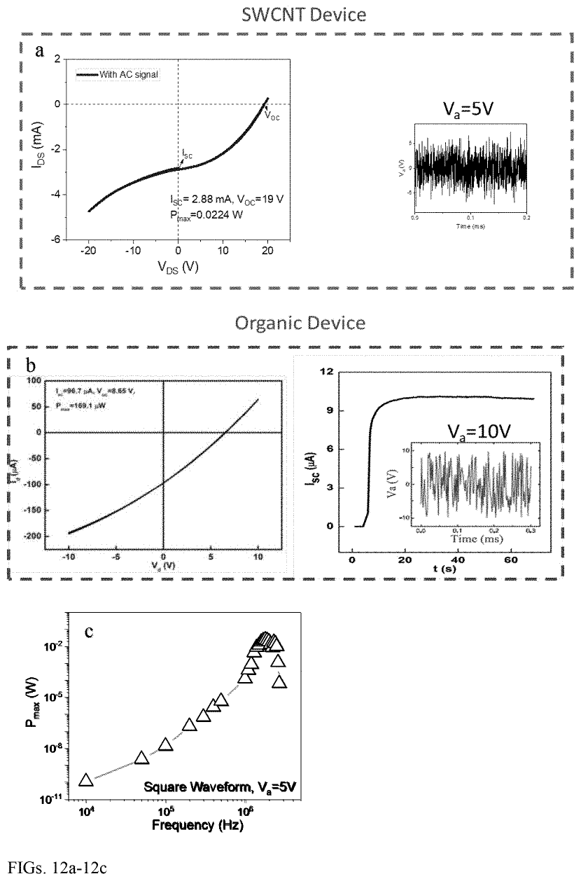

FIGS. 13a-13e depict a perovskite electronic ratchet comprising a 2D layered perovskite (C₇H₁₀N) electronic ratchet. 13(a) is a digital microscopic image of 2D layered perovskite device; 13(b) depicts current-voltage (I-V) curves of 2D layered perovskite device. 13(c) depicts field effect transistor measurement of 2D layered perovskite device. 13(d, e) depict channel current (IDS) of the 2D layered perovskite device as a function of applied signal frequency (AC, square waveform, Va=5V).

FIGS. 14a-14c depict a perovskite electronic ratchet comprising a nanocrystal (CsPbI₃) electronic ratchet (a) Digital microscopic image of perovskite nanocrystal device; (b) channel current (IDS) of the perovskite nanocrystal device as a function of time under application of a AC signal (AC, 3 kHz, square waveform, Va=5V); (c) channel current (IDS) of the perovskite nanocrystal device as a function of applied signal frequency (AC, square waveform, Va=5V).

FIG. 15 depicts an embodiment of a 2D (PEA)₂PbI₄ electronic ratchet and an exemplary embodiment of transforming noise to current and voltage.

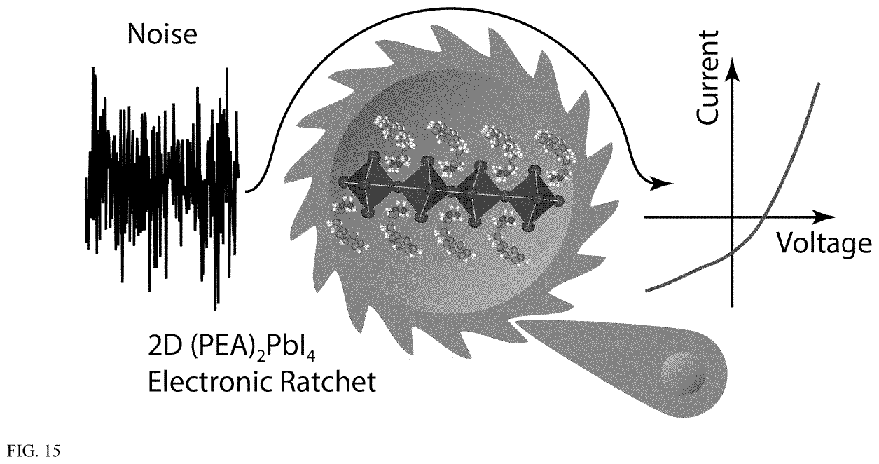

FIGS. 16a, 16b, 16c and 16d depict a characteristic performance of a (PEA)₂PbI₄ field-effect transistor (FET). FIG. 16a depicts an optical image and schematic image of 2D perovskite FET device, and the scale bar is 1 mm. FIG. 16b depicts a transfer curve before voltage stress, FIG. 16c depicts output curves for V_{G}=0 V before (black trace) and after (red trace) voltage stress, and FIG. 16d depicts an output curve of the stressed device under application of unbiased square-wave signal to the gate electrode.

FIGS. 17a, 17b, 17c, and 17d depict an embodiment of the device performance of a (PEA)₂PbI₄ electronic ratchet under voltage stress. FIG. 17a depicts a short-circuit current, I_{sc}, FIG. 17a depicts an open-circuit voltage, V_{oc}, and FIG. 17c depicts a maximum output power, Pₘₐₓ, for the ratchet as a function of the frequency of the applied AC square wave (Va=±5 V amplitude). FIG. 17d depicts a short-circuit current, I_{sc}, under application of simulated electronic noise (Vₐ=±5 V amplitude). The insets show the nature of the applied gate bias.

FIG. 18 depicts the dependence of the short-circuit (source-drain) current, I_{sc}, of a (PEA)₂PbI₄ electronic ratchet device on the voltage amplitude of the simulated noise input signal.

FIGS. 19a and 19b depict the dependence of the short-circuit (source-drain) current, I_{sc}, of a (PEA)₂PbI₄ electronic ratchet device on the voltage amplitude of AC input signal at 5000 Hz (see FIG. 19a) and 70000 Hz (see FIG. 19b).

FIGS. 20a, 20b, and 20c depict scanning Kelvin probe microscopy of the channel of a (PEA)₂PbI₄ field-effect transistor (FET) before (black traces) and after (red traces) voltage stress: (FIG. 20a) Topography and (FIG. 20b) surface potential, relative to that measured on top of gold contacts. FIG. 20c is a schematic of the transistor channel after voltage stress resulting in migration of positively-charged iodide vacancy motion towards the drain electrode, illustrating accumulation of positive charges near to the drain electrode.

FIGS. 21a, 21b, 21c, 21d, 21e, 21f, 21g, and 21h depict topography and contact potential difference for the forward and reverse scan directions for a (PEA)₂PbI₄ electronic ratchet device (left FIGS. 21a, 21b, 21c, and 21d) before and (right FIGS. 21 e, 21f, 21g, and 21h) after voltage stress (source grounded at 0 V and a −20 V bias applied to drain for 15 minutes). The dashed blue rectangles indicate the area that was averaged to produce the lines scans in FIGS. 16a, 16b, and 16c.

FIG. 22 depicts the variation of the ratio (Isc/Isc_inital) vs. lasting time of the perovskite electronic ratchet after the voltage bias treatment.

FIGS. 23a, 23b, 23c, 23d, 23e, 23f, 23g, and 23h depict TOF-SIMS characterization of iodine ion distribution in the device channel. (FIG. 23a) Optical microscopic image of device channel; (FIG. 23b) The Cs₂I⁺ ion intensity mapping of the channel of the control device; (FIG. 23c) The Cs₂I⁺ ion intensity mapping of the device channel after voltage stress (15 min., −15V applied to drain); (FIG. 23d) The Cs₂I⁺ ion intensity mapping of the channel of the control device; The Cs₂I⁺ ion intensity mapping of the device channel after combined voltage stress with light bias (15 min., −15V applied to drain, 405 nm laser illumination); (FIG. 23e) Schematic of iodine ion and vacancy movement under the voltage bias; (FIG. 23f) Average intensity variation of Cs₂I⁺ ion with scanning length across the channel of the control device; (FIG. 23g) Average intensity variation of Cs₂I⁺ ion with scanning length across the channel device after voltage stress; The intensity variation of Cs₂I⁺ ion with scanning length across the channel of the control device; (FIG. 23h) Average intensity variation of Cs₂I⁺ ion with scanning length across the channel device combined voltage bias with light bias.

FIG. 24 depicts device performance of a (PEA)₂PbI₄ electronic ratchet under the voltage stress and voltage stress with laser illumination. FIG. 24(a) is a schematic of the experimental setup of voltage stress with 405 nm laser illumination, FIG. 24(b) depicts current to voltage output curves for V_{G}=0 V before (black trace) and after (red trace) voltage stress, and after voltage stress with 405 nm laser illumination. FIG. 24(c) depicts short-circuit current, I_{sc}, under application of simulated electronic noise (Vₐ=±5 V amplitude) under the voltage stress and under voltage stress with laser illumination. The insets show the nature of the applied gate bias.

FIGS. 25a and 25b depict X-ray diffraction patterns. FIG. 25a depicts normalized powder X-ray diffraction patterns measured (top) and calculated (bottom) and FIG. 25b depicts absorption spectrum of a (PEA)₂PbI₄ thin film on a glass substrate. The powder X-ray diffraction patterns indicate that the (PEA)₂PbI₄ crystal structure is oriented with the ‘sheets’ of octahedral PbI₆ oriented parallel to the substrate surface.

FIG. 26a is a schematic of field-effect transistor measurement geometry and FIG. 26b is an optical microscopic image of an embodiment of a (PEA)₂PbI₄ electronic ratchet device.

### DETAILED DESCRIPTION

Electronic ratchets are highly asymmetric systems that operate out of equilibrium and produce net current when driven by zero time-average energy fields such as AC voltage. In an embodiment, structural asymmetries are induced to transfer the non-directional fluctuating source of energy to a directional motion of energy. In an embodiment, the asymmetry of the potential leads to the directed transport of particles. In an embodiment, disclosed herein are semiconducting single-walled carbon nanotubes (s-SWCNTs) as the active channel semiconductor in electronic ratchets. s-SWCNTs are an attractive choice, since their chemical structure and electronic properties make them amenable to remote doping strategies, which produce highly conductive thin films even in the case of randomly aligned, porous s-SWCNT networks. In an embodiment, as used herein, the term “semi-SWCNT” can mean a semiconducting SWCNT material.

In an embodiment, SWCNTs are the active semiconductor in “electronic ratchet” energy conversion devices. In an embodiment, SWCNTs have carrier mobilities up to about 1×10⁵ cm² V⁻¹ s⁻¹. In an embodiment, SWCNTs are structures with are ultrathin and are easily integrated with other semiconducting systems. In another embodiment, two device architectures incorporating tailored SWCNT networks are disclosed to demonstrate proof-of-principle rectification of time-varying (alternating current) input potentials to produce a direct current output. Disclosed herein are methods to fabricate SWCNT networks with (1) spatially varying SWCNT content and/or (2) spatial control over the carrier density profile, to enhance the performance of the electronic ratchet.

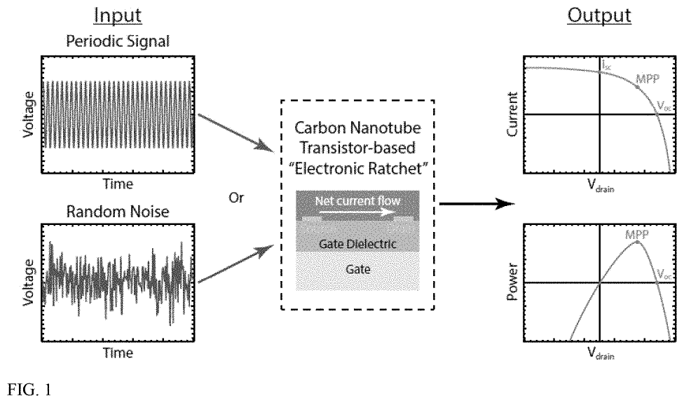

Typically, solution-processed, nanostructured electronic devices exhibit a disordered structural and electronic landscape. This means that, in the absence of an asymmetric external stimulus (e.g., magnetic or electric field), these devices suffer from randomized carrier transport that inhibits directional current. In contrast, “electronic ratchets”, a form of “Brownian motor”, are non-equilibrium systems that employ spatial asymmetry to harness time-varying (but zero time average) potentials to bias the motion of randomly moving carriers. Such devices can rectify both periodic and random (such as thermal noise) input driving potentials (see FIG. 1) at frequencies in the 100 s of Hz to >1 MHz range, with power efficiencies that suggest potential as compact energy harvesting devices to drive low-power electronic circuitry (e.g., wireless sensors, radio frequency identification tags, etc.). The performance of these devices depends on factors such as the length scales, amplitude, and asymmetry of the time-dependent input potential, as well as material properties like the density and mobility of the charge carriers. Theoretical calculations suggest that the material properties and device characteristics have the potential to demonstrate charge displacement and power efficiencies of 50% and 7%, respectively.

Several organic semiconductors have been explored as the active component of an electronic ratchet, including molecular crystals and heavily-doped conjugated polymers. However, their performance is limited by the carrier densities and mobilities achievable in such systems. Single-walled carbon nanotubes (SWCNTs) represent a unique material system to overcome these limitations, since they demonstrate very large carrier mobilities and can be heavily doped (reaching degenerate, near metallic conductivity even in randomly oriented networks). To date, SWCNTs have not been explored within the context of electronic ratchet devices and applications. In an embodiment, the polymer-enabled selective extraction processes as disclosed herein enable the preparation and evaluation of SWCNT networks of semiconducting nanotubes with varying diameter distributions. These electronic ratchets are different from existing work on organic electronic ratchets, which have focused on prototypical organic semiconductors (e.g., pentacene and poly[3-hexylthiophene]), where control over the intrinsic electronic properties is more difficult and where the doping strategies commonly used for organic semiconductors result in morphological disruptions that can severely limit carrier transport.

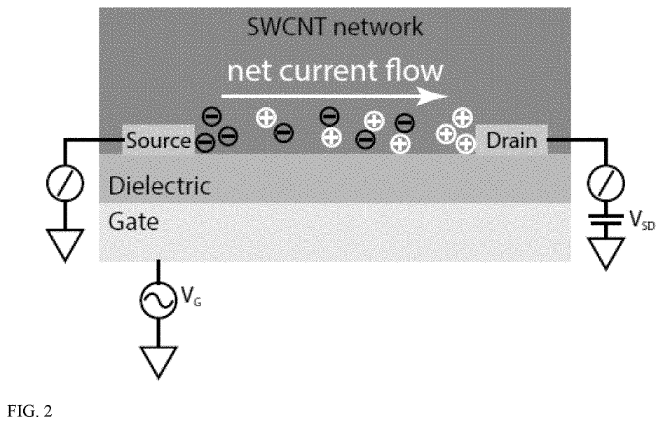

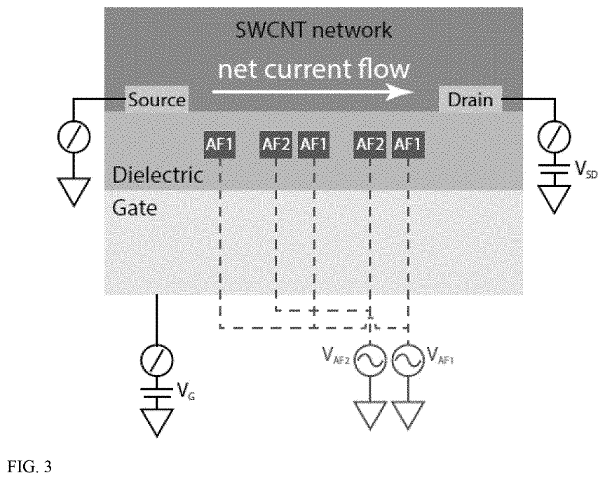

As described above, the function of an electronic ratchet device depends on the ability to establish spatial asymmetry in the potential within the charge-transporting layer in a device architecture resembling a simple field-effect transistor. To date, two approaches have been used to generate this spatial asymmetry in organic electronic ratchets: (1) voltage stress-induced spatial separation of cations and anions in the doped semiconductor (ionic-organic ratchet, see FIG. 2) or (2) the inclusion of asymmetrically-spaced interdigitated electrodes embedded within the gate dielectric (see FIG. 3).

Spatially-Controlled Dopant Profiles:

In an embodiment, ionic-organic ratchets are disclosed which use a device geometry (that can even be fabricated on substrates comprised of aluminum foil and scotch tape) that uses heavily-doped SWCNT networks as the semiconducting material (see FIG. 2). In an embodiment, this carrier doping allows for fine control over the carrier density in SWCNT networks, through the use of charge-transfer dopants.

For SWCNT-based systems, strategies were developed to enable micron-scale control over the dopant profiles within the channel of the electronic ratchet device. Spatial control was provided by voltage stressing procedures developed for polymer-based electronic ratchets.

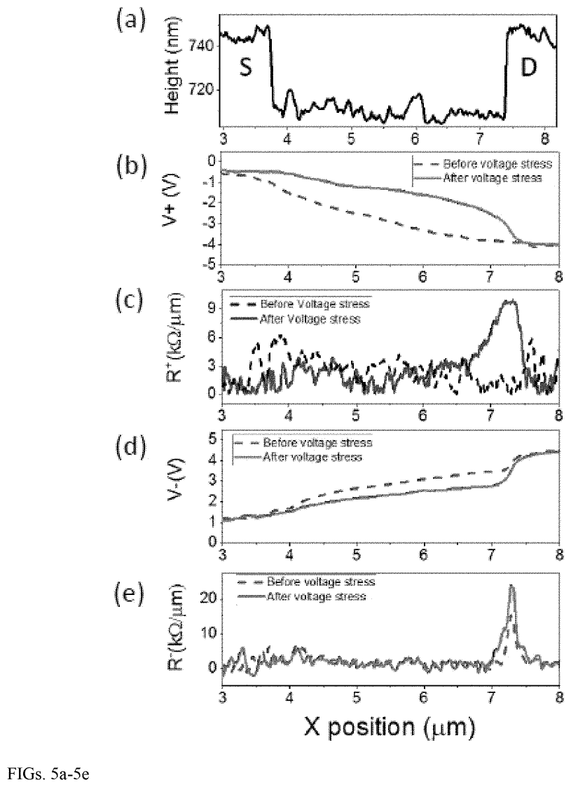

In another embodiment, fabrication and post-processing approaches were used to control the spatial dopant profile, such as direct-write optical patterning of dopant density through laser-induced dopant removal, within the SWCNT network. Scanning Kelvin probe microscopy (SKPM) was used to elucidate properties (charge density, potential, & electric field) associated with the dopant profile within the channel (see FIG. 5). SWCNTs can be doped using a variety of charge-transfer dopants by using dopants such as tetracyanoquinodimethane derivatives or amine-based molecules.

Asymmetric interdigitated buried electrodes: In an embodiment, the product of fabrication of complex device architectures containing asymmetric interdigitated electrodes is depicted in (FIG. 3). This architecture allows for the investigation of the impact of fundamental material transport properties (i.e., electronic bandgap, charge carrier mobility) and geometrical effects (i.e., electrode patterns and spacing) on the output characteristics (i.e., maximum current and power) of the device. Devices were developed where the asymmetry is afforded by both spatial control of dopant density and asymmetric device architectures.

Fabrication of Electronic Ratchet Substrates:

The substrates for the bottom-gate, bottom-contact, and three-terminal devices were fabricated on a commercially-available 300 nm SiO₂/p-doped Silicon (Si) wafer, which represents the gate electrode, The first and second electrodes were patterned using standard optical lithography techniques followed by thermal evaporation of the 5 nm-thick titanium (Ti) and 20 nm-thick gold (Au), to form channels with 25 μm, 10 μm, 5 μm channel lengths (LCH) and 1000 μm channel width (WCH). The photoresist was removed using a standard lift-off process to expose the electrode pattern.

Device Measurements:

Field Effect Transistor Measurement:

Transport measurements and device performance characterization, in the field-effect transistor geometry, were performed in the helium-filled glovebox using two Keithley 2400 SourceMeter Source Measure Unit (SMU). One is used to supply the source-drain voltage and the other is used to supply the gate voltage. Control of the Keithley 2400 SMU is provided by a custom-written LabVIEW interface, which enables real-time collection of the experimental data (source-drain current and leakage current). The typical applied source-drain bias (VSD) is 0.1 V, and the gate voltage (VG) is swept over the range −40 to +30 V (typically, but not limited to, with an increment of 0.7 V per step).

To assess the effect of various parameters on the charge-carrier transport properties of our semiconductor materials, the carrier mobility was calculated from the linear portion of the transistor transfer curve (IDS vs. VG) using standard parallel plate capacitance model:

$${μ}_{p} = \frac{\partial {I}_{S D}}{\partial {V}_{G}} \frac{1}{{V}_{S D}} \frac{1}{{C}_{o x}} \frac{{L}_{C H}}{{W}_{C H}}$$

where C_{OX} is the oxide capacitance per unit area of SiO₂, and all other parameters are as defined above.

Current to Voltage (IV) Measurement:

Two-terminal (source-drain) current-voltage (I-V) measurements were also performed in the helium-filled glovebox by using one of the Keithley 2400 SourceMeter SMUs, controlled via a custom-programmed software, to collect experimental data.

Electronic Ratchet Measurement:

The electronic ratchet measurements were performed using a Keithley 2400 SourceMeter SMU (with custom-written LabVIEW interface) and either an Agilent 33220A signal generator and Key sight 81150A Pulse-/Function-/Arbitrary-noise Generator providing the sources of alternating current/oscillating (AC) signals to the gate electrode of the ratchet device.

Preparation of Semiconducting Single-Walled Carbon Nanotube (s-SWCNT) Electronic Ratchet:

Enriched semiconducting single-walled carbon nanotube (s-SWCNT) inks were prepared via selective extraction of the semiconducting nanotube species from the raw carbon nanotube soot, using a solution-phase extraction process that employs fluorene-based polymers. Films of polymer-wrapped nanotubes were fabricated by deposition of the enriched s-SWCNT ink through a shadow mask onto the channel of the pre-patterned substrates via an ultrasonic spray deposition technique. The excess polymer is removed via a solution-phase soaking process, to densify the carbon nanotubes into an undoped network.

Undoped s-SWCNT Device:

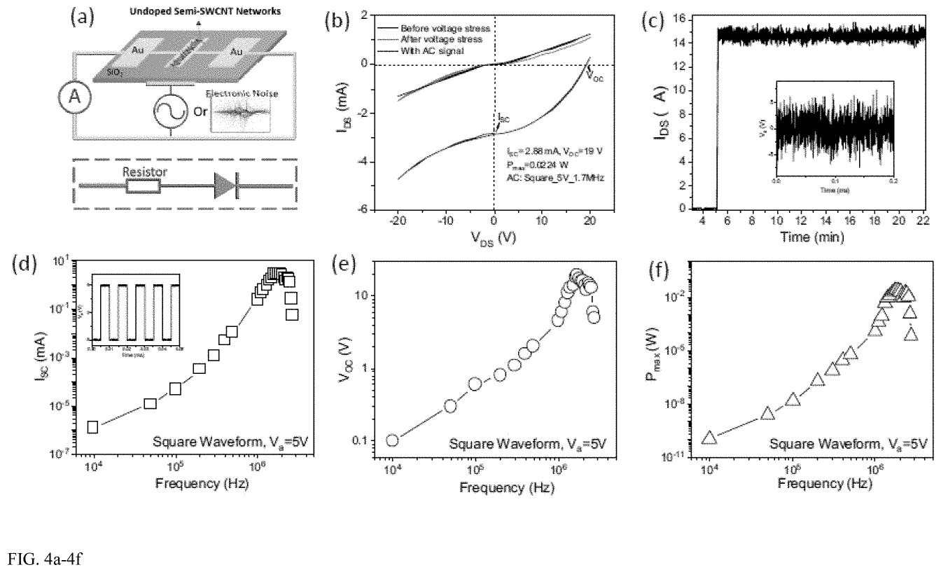

The devices constructed from the undoped s-SWCNT networks exhibit typical transport behavior of thin-film field-effect transistors, with p-type majority carriers (i.e., holes) that arise from adventitious doping due to adsorbed oxygen. In an embodiment, to enable electronic ratchet behavior, a bias (voltage stress) of 15 volts is applied between the first and second electrodes (source and drain contacts) for at least about 10 minutes. After application of this voltage stress, the current-voltage (I-V) measured between the first and second electrodes (source and drain contacts) exhibits non-linear conductance behavior (see FIG. 4b), indicative of a redistribution of carriers and/or dopant counterions within the carbon nanotube network inside the channel. Scanning Kelvin probe microscopy (SKPM) measurements indicate that this redistribution results in an increase in differential resistance at one of the contacts (see FIG. 5), which can be assigned to a rectifying junction that favors hole extraction at that contact. Application of a square-wave bias signal to the gate electrode results in rectifying behavior in the fourth quadrant of the ISD vs. VSD plot (see FIG. 4b). Application of random noise to the gate electrode (FIG. 4c inset) results in the generation of a short-circuit current that is stable over the course of several minutes (FIG. 4c). The frequency-dependent ratchet device performance was evaluated by applying a square-wave AC bias (FIG. 4d inset) of varying frequency. FIGS. 4d, 4e, and 4f illustrate the frequency-dependent short-circuit current (FIG. 4d), open-circuit voltage (FIG. 4e), and maximum power output (FIG. 4f).

P-Type Doped s-SWCNT Device:

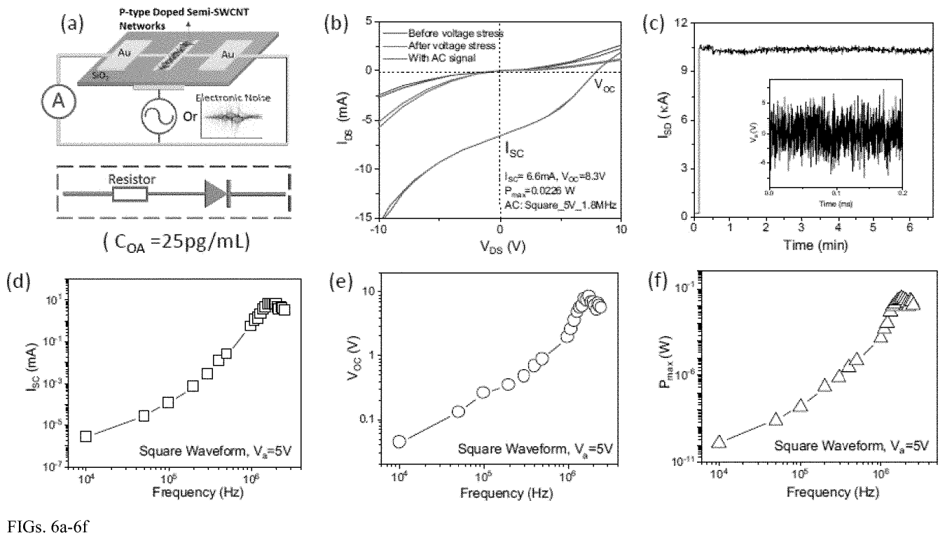

The undoped s-SWCNT networks were immersed into solutions of the one-electron oxidant triethyloxonium hexachloroantimonate (OA) in dichloroethane (DCE) at 78° C. for 1 min. A short (less than about 2 seconds) acetone soak (at room temperature) was used to remove excess dopant residue from the surface of the s-SWCNT network. Studies of p-type doped s-SWCNT transistors suggest that the transistor device performance is sensitive to the charge-carrier concentration, which is dependent on the conditions employed during the solution-phase doping step (i.e., dopant concentration, immersion time, temperature, etc). For the ratchet devices, an OA solution was used at concentrations of 1 pg/mL, 5 pg/mL and 25 pg/mL. As for the undoped s-SWCNT ratchet, a voltage stress (15 volts is applied between the first and second electrodes (source and drain contacts) for at least about 10 minutes) is required to emphasize the asymmetry in the channel of the device (FIG. 6b). As for the undoped device, application of a square-wave bias signal to the gate electrode results in rectifying behavior in the fourth quadrant of the ISD vs. VSD plot (FIG. 6b). Application of random noise to the gate electrode (FIG. 6c inset) results in generation of a short-circuit current that is stable over the course of several minutes (FIG. 6c). The frequency-dependent ratchet device performance was evaluated by applying a square-wave AC bias of varying frequency. FIGS. 6d, 6e, and 6f illustrate the frequency-dependent short-circuit current (FIG. 6d), open-circuit voltage (FIG. 6e), and maximum power output (FIG. 6f). The doped devices exhibit an improvement in the short-circuit current due to an improvement in the device conductance due to the charge-carrier doping, whereas the open-circuit voltage is decreased. This trade-off, at least for these device preparation conditions, appears to result in similar power conversion performance (see FIGS. 4f and 6f).

N-Type Doped s-SWCNT Device:

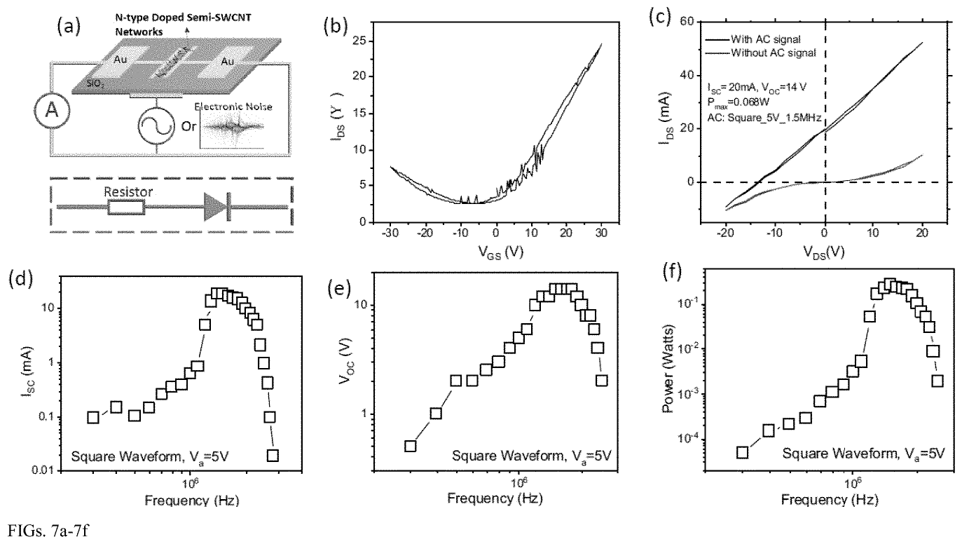

Following a similar procedure to the p-type doped device, the undoped s-SWCNT networks were immersed into solutions of 0.0035 mg/mL concentration Benzyl Viologen (BV) at room temperature in a glovebox filled with an inert atmosphere for 5 s, followed by a short (less than about 2 seconds) acetone soak (at room temperature) to remove excess dopant residue from the surface of the s-SWCNT network. These doping conditions result in a transistor that exhibits ambipolar transport (FIG. 7b), when a sufficiently large gate bias is applied to overcome majority n-type carriers. In the ratchet experiment the device exhibits n-type transport, albeit with poor rectification characteristics (see FIG. 7c). However, the frequency-dependent ratchet device performance, evaluated by applying a square-wave AC bias of varying frequency, is similar to (or possibly superior to) the undoped and p-type doped devices. FIGS. 7d, 7e, and 7f illustrate the frequency-dependent short-circuit current (FIG. 7d), open-circuit voltage (FIG. 7e), and maximum power output (FIG. 7f) for an n-type doped s-SWCNT electronic ratchet.

Built-In Junction SWCNT Device:

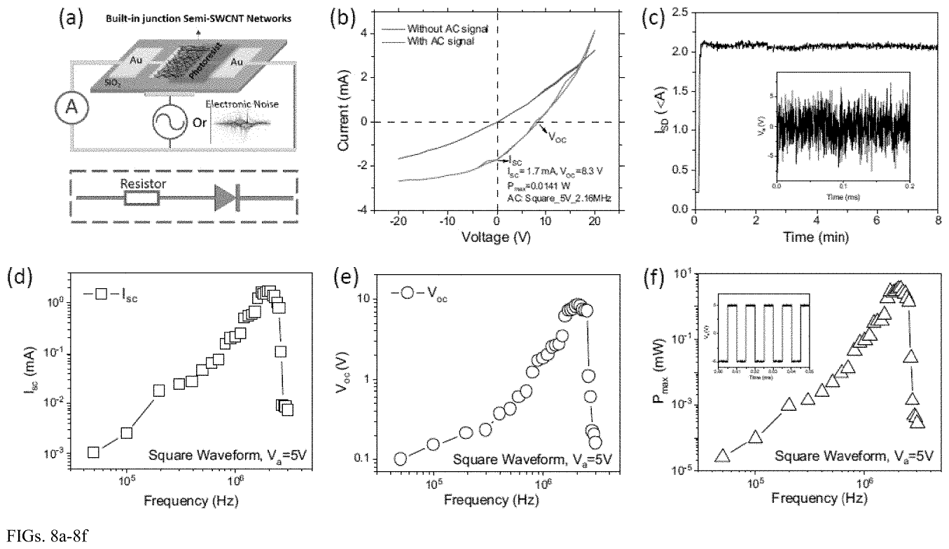

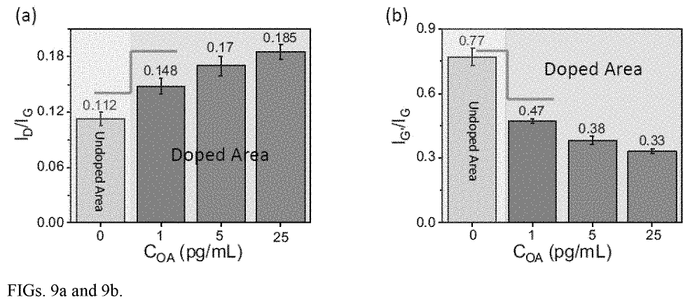

To generate an asymmetrical charge-carrier profile in the channel, a photo mask was generated using standard optical lithography methods on a photoresist (Microchem Shipley S1818 positive photoresist) deposited on top of the undoped s-SWCNT network. Exposure of the photoresist, followed by a standard removal process to remove the exposed photoresist, leaves behind a photoresist layer that protects one region of the channel from the dopant solution into which the device is immersed (i.e., OA solutions of 1 pg/mL, 5 pg/mL and 25 pg/mL concentration for 1 min at 78° C.). This methodology results in a partially-doped s-SWCNT channel (for channels with LCH=10 μm and 25 μm). The schematic of the built-in junction SWCNT device is shown in FIG. 8(a). Since an asymmetric doping profile in the s-SWCNT channel was created using the optical lithography followed by solution-phase doping, the device exhibits rectifying behavior, which is demonstrated by the black curve in FIG. 8(b) with applied AC signal. The red curve in FIG. 8(b) shows the IV response of the s-SWCNT device under the AC signal as the gate voltage input. Application of random noise to the gate electrode (FIG. 8c inset) results in generation of a short-circuit current that is stable over the course of several minutes (FIG. 8c). The frequency-dependent ratchet device performance was evaluated by applying a square-wave AC bias of varying frequency. FIGS. 8d, 8e, and 8f illustrate the frequency-dependent short-circuit current (FIG. 8d), open-circuit voltage (FIG. 8e), and maximum power output (FIG. 8f). The built-in doping profile was characterized by using confocal Raman microscopy (see FIG. 9), through comparing the intensity ratios (ID/IG and IG′/IG) in the undoped and doped area, since these intensity ratios are sensitive to the doping density. This data shows a clear change in the intensity ratios, which are also monotonically dependent on the concentration of the dopant solution used in the solution-phase doping step. The device with the built-in asymmetric doping profile exhibits a more stable short-circuit current output under the application of an AC voltage bias to the gate electrode, when compared to the voltage stressed devices.

Thus, in an embodiment, as disclosed herein are electronic ratchets comprising semiconducting enriched SWCNT networks that have much higher carrier mobility than organic or ion-doped organic materials. Also disclosed herein are electronic ratchets that by applying a high voltage bias, the potential profile of electronic ratchets comprising a semiconducting enriched SWCNT network device can be manipulated to form an asymmetric potential profile (diode profile). Also disclosed herein are electronic ratchets comprising semiconducting enriched SWCNTs having the ability to transfer both regular waveform signal and noise signal to direct current. In another embodiment, disclosed herein are electronic ratchets comprising semiconducting enriched SWCNT that demonstrate much better performance than organic electronic ratchet devices.

Preparation of Electronic Ratchets Using Perovskites with Reduced Dimensionality:

Two-dimensional (2D) perovskite device: In an embodiment, disclosed herein are “soft” lead-halide perovskites used to fabricate and study electronic ratchet energy harvesting devices, where intentional and controlled ion movement is both achievable and necessary to optimize performance. The perovskite containing electronic ratchet devices were constructed via drop-casting deposition of a thin film of phenylethylamine lead iodide (C₆H₅C₂H₄NH₃)₂PbI₄; PEPI) perovskite solution onto the channel of the pre-patterned substrates, in a nitrogen-filled glovebox.

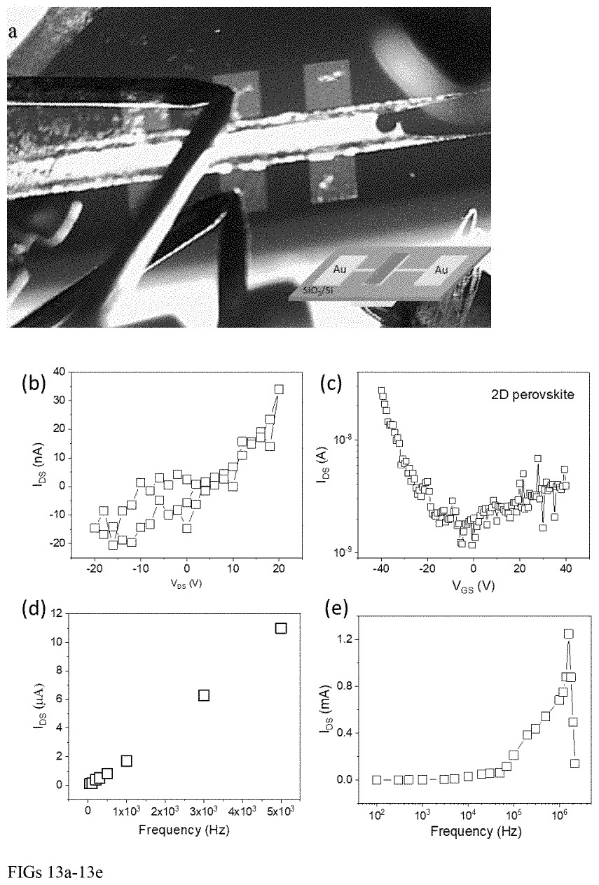

The microscopic image of the 2D perovskite device was shown in FIG. 13a and the field effect transistor measurement demonstrates that 2D perovskite device has a bipolar electronic property and hole (P-type) is the major carrier (FIG. 13c). After the voltage stress of NCs device, the IV curve shows more asymmetric than that of before voltage stress (FIG. 13b), the short circuit current (ISC) performance of NCs device is demonstrated in FIG. 13(d, e), and the ISC show a gradual increase versus the frequency of AC signals applied as the gate voltage.

Perovskite nanocrystal device: The devices were constructed via spin-coating deposition of a thin film of cesium lead iodide (CsPbI₃) nanocrystals (NCs) onto the channel of the pre-patterned substrates, in a nitrogen-filled glovebox.

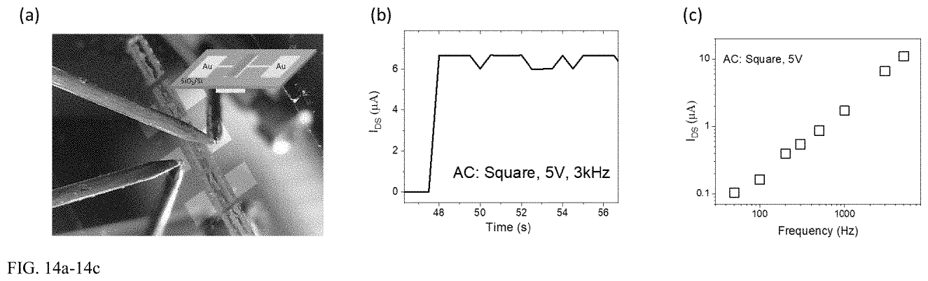

The microscopic image of the perovskite nanocrystals device (NCs device) is depicted in FIG. 14a and the field effect transistor measurement demonstrates that perovskite nanocrystal device has a p-type (hole) carrier transport. The short circuit current (ISC) performance of NCs device is demonstrated in FIG. 14 (b, c), and there is an almost linear increase of ISC with the increasing of frequencies of AC signals applied as the gate voltage.

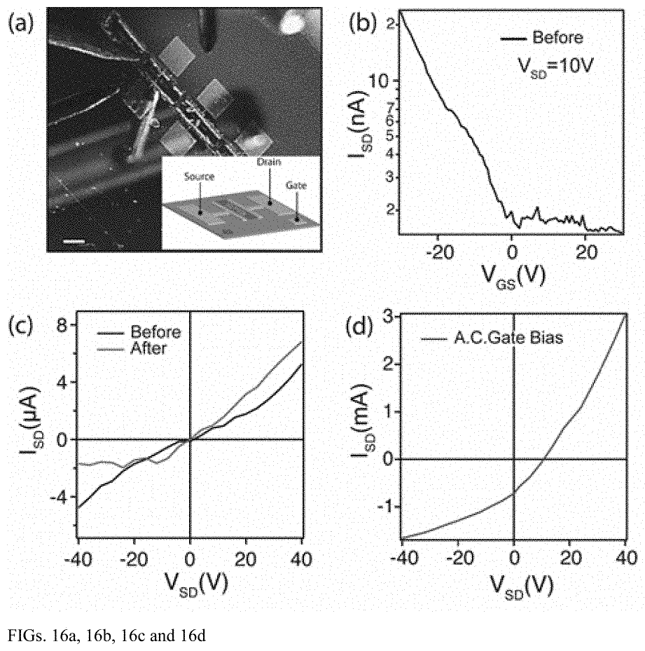

A (PEA)₂PbI₄ field-effect transistor (FET): In an embodiment, disclosed herein is a new type of organic-inorganic electronic device based on a hybrid two-dimensional (2D) lead-halide perovskite material, phenethylammonium (PEA) lead iodide ((PEA)₂PbI₄). FIG. 16a shows the schematic and optical image of the 2D perovskite FET device (FIG. 16a) that we use to create our electronic ratchet. A characteristic FET transfer curve (FIG. 16b), and output curve (FIG. 16c; black trace) show p-type transport and symmetric current-voltage (I-V) response. To create a spatial and electronic asymmetry within the channel, a “voltage stress” was applied between the source and drain electrodes, wherein the source was grounded at 0 V and a −15 V to −20 V bias was applied to the drain for 15 minutes. After the 15-minute voltage stress, the I-V response becomes asymmetric (FIG. 16c, red curve). The generated asymmetry in turn enables the conversion of a 0 V time-averaged square-wave AC signal (Va=±5 V amplitude, 50% duty cycle, applied to the gate electrode) into direct current and power (FIG. 16d), a characteristic function of an electronic ratchet.

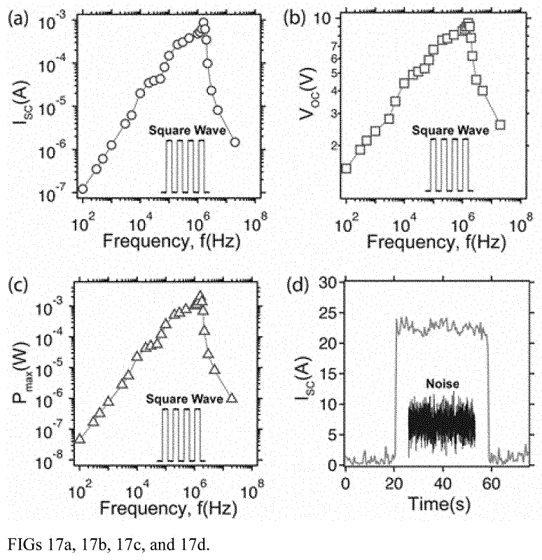

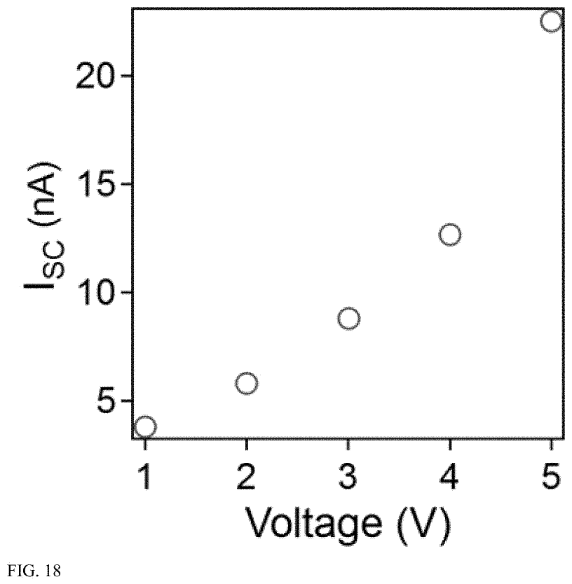

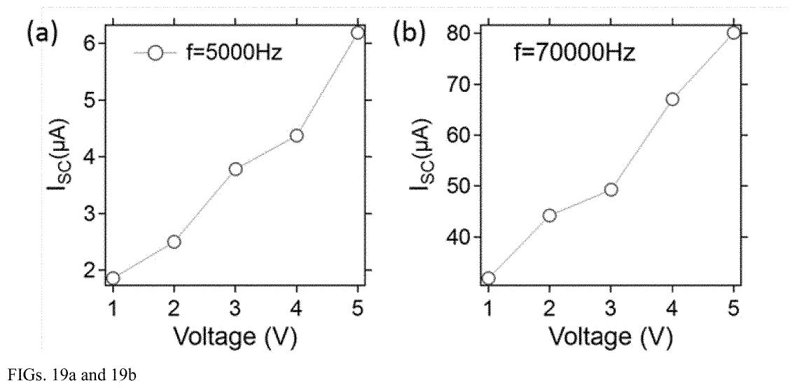

Upon successfully introducing conductance asymmetry into the 2D perovskite FET channel, we set out to clearly demonstrate the performance of our prototype perovskite electronic ratchet. FIGS. 17a-c show the dependence of the electronic ratchet I-V performance (i.e., short-circuit current, I_{sc}, open-circuit voltage, V_{oc}, and maximum output power, Pₘₐₓ) on the frequency of the applied square-wave AC signal to the gate electrode. Both the I_{sc} and V_{oc} increase with frequency up until their maximum values at ca. 1.6 MHz, where the device performance metrics I_{sc}=0.8 mA, V_{oc}=10 V, Pₘₐₓ=2 mW compare favourably with those measured for ionic-organic ratchets. As discussed earlier, an attractive potential application of electronic ratchets is their ability to harvest energy from electromagnetic noise. To evaluate the performance of our 2D perovskite device under these conditions, we apply a simulated noise signal (0 V time-averaged bias, ±5 V amplitude) to the gate and monitor the short-circuit current generated by the device (FIG. 17d), which is about 23 nA and remains constant over the duration of the applied noise bias. FIGS. 18 and 19 depict that I_{SC} increases with the amplitude of the applied noise bias and AC signals. In an embodiment, FIG. 18 depicts dependence of I_{sc} on applied noise voltage. FIGS. 19a and 19b depict an embodiment of the dependence of I_{sc} on applied square-wave AC voltage at 5000 Hz (FIG. 19a) and at 70000 Hz (FIG. 19b).

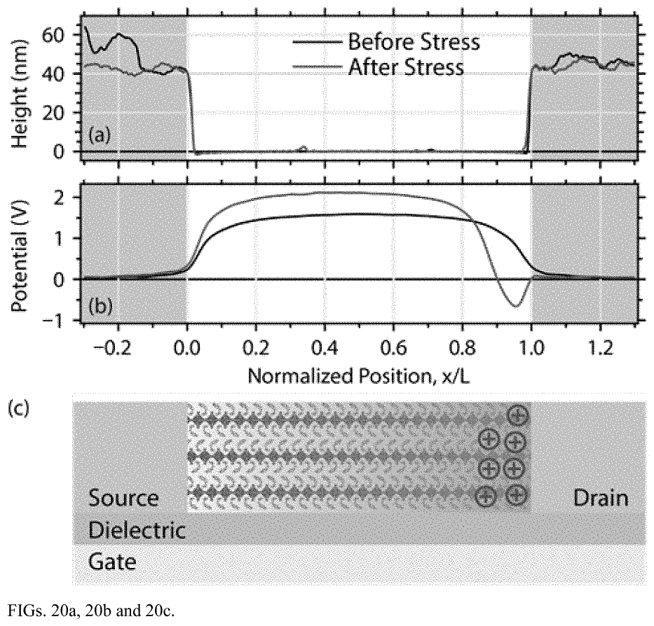

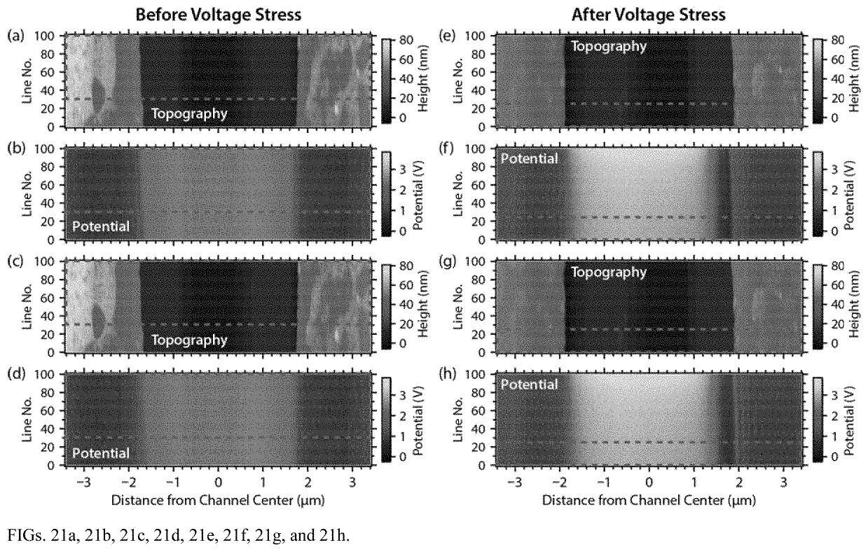

To gain a deeper understanding of the mechanism underlying the asymmetric conductance that enables the ratchet behaviour of the 2D perovskite, we turn to spatially resolved measurements of the potential and ion distributions. In order to spatially resolve the potential distribution that results from the applied voltage stress, we used scanning Kelvin probe force microscopy (KPFM) measurements of a (PEA)₂PbI₄ FET. These measurements illustrate that the 15-minute voltage stress induces a significant asymmetry in the surface potential distribution close to the drain electrode (FIG. 20b). The profiles shown in FIG. 20 were extracted from topography and surface potential images of the channel. FIGS. 21a through 21h depict additional topography and surface potential images of an exemplary device whose properties are also depicted in FIG. 16.

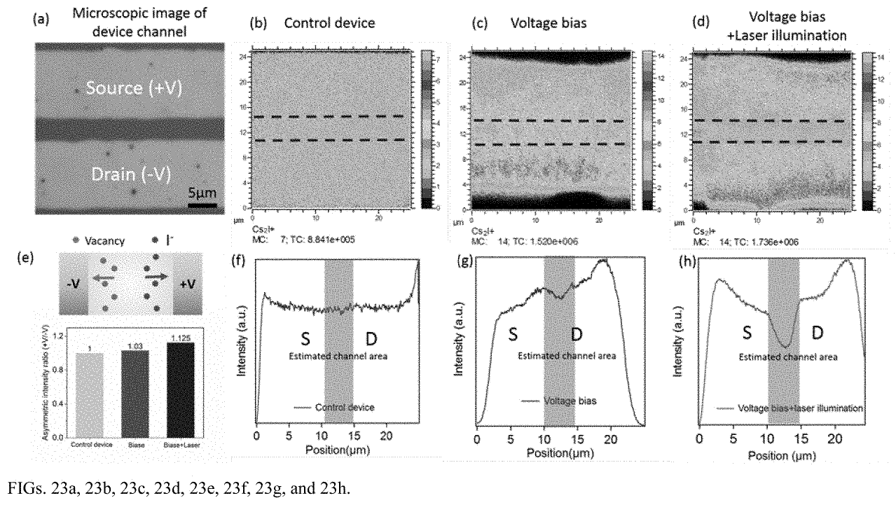

We hypothesized that the conductance and potential asymmetries observed in FIGS. 16 and 20 are caused by the known propensity for field-induced migration of positively-charged iodide vacancies, (VI)+, within the perovskite. While a similar mechanism has been proposed to explain the asymmetries observed in I-V curves and SKPM maps of organic ratchets, these proposals have not been confirmed by direct measurements of ion redistribution within those devices. As such, we turned to Time-of-Flight Secondary Ion Mass Spectrometry (TOF-SIMS), which has been used as a sensitive probe of spatial changes in atomic stoichiometry in lead-halide perovskites (FIG. 23). TOF-SIMS spatial maps within the FET channel demonstrate that a control device that undergoes no voltage stress have no appreciable spatial variation of the iodide concentration (FIGS. 23b and 23f). In contrast, when the same device is voltage stressed, positively charged iodide vacancies accumulate at the negatively biased source electrode (FIGS. 23c and 23g). This result is consistent with numerous studies reporting relatively facile iodide vacancy migration in voltage-stressed perovskite solar cells.

The combination of the TOF-SIMS and SKPM paint a clear picture of the operational mechanism at play in the voltage-stressed 2D perovskite ratchet. After the voltage stress, accumulation of positively charged iodide vacancies at the drain electrode creates a barrier to hole injection into the channel, resulting in a rectifying drain electrode, but would only have a minor influence on hole injection or extraction at the source electrode. This ion redistribution provides the rectifying function of the ratchet, similar to the mechanism proposed for ionic-organic ratchets. Thus, the operation of the perovskite electronic ratchet under a time-averaged zero-bias gate signal and zero source-drain bias can be described as such. When the negative voltage bias of the input signal is applied to the gate electrode, holes will accumulate in the channel from the source electrode, although the large V_{oc} (vide supra) suggests that there may also be some injection from the drain electrode. Subsequently, when the gate voltage is switched to positive bias, holes will be extracted to both the source and drain contacts, resulting in a net flow of holes from source to drain. Since both contacts are gold, and thus no field is formed as a result of different contact work functions, the direction of current flow is determined solely by the asymmetric potential in the channel that results from voltage stress-induced ion migration.

With this mechanism in mind, we hypothesized that combining the voltage stress with an additional light bias should enhance the achievable conductance and potential asymmetry and improve the performance of perovskite electronic ratchets. This hypothesis is based off of the previously observed reduction in activation energy for ion migration in the presence of illumination above the optical bandgap of lead-halide perovskites. Thus, in our FET geometry, the simultaneous application of electric field and light bias should drive more ions and vacancies to the source and drain electrodes, forming a more asymmetric ion distribution across the device channel relative to a device that is solely voltage stressed.

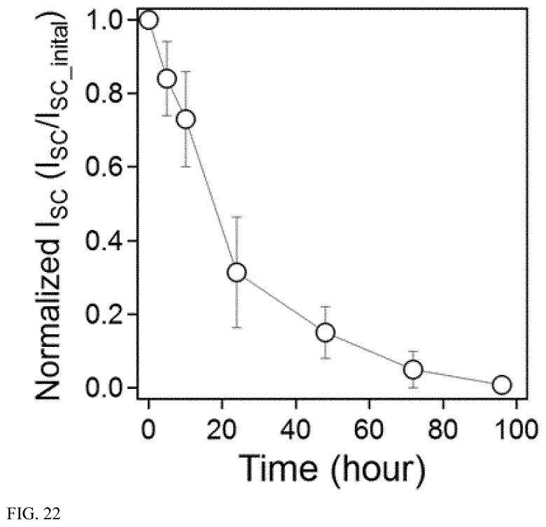

To test this hypothesis, we compared the properties of a (PEA)₂PbI₄ FET device subjected to voltage stress or to voltage stress combined with light bias. The sample was first characterized before and after the voltage stress (−15V, 15 mins). Following characterization of the voltage-stressed device, the device was left to recover to its original state inside the N₂ glovebox, which normally takes four days for a full recovery (FIG. 22). The device was then illuminated with a 405 nm wavelength laser (P˜5 mW, spot size: 0.5 mm², power density: 10³ mW/cm²) while simultaneously applying a −15 V voltage bias to the drain electrode for 15 minutes. A schematic of this experimental setup is shown in FIG. 4a. FIG. 4b demonstrates that the I-V curve under light bias and voltage stress qualitatively becomes more asymmetric than that under voltage stress only.

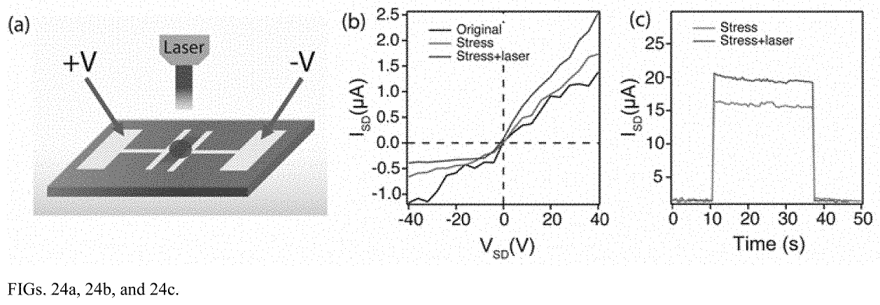

FIG. 24c shows the electronic ratchet performance of our 2D perovskite device following either voltage stress or voltage stress with laser illumination, where the driving stimulus is a simulated noise signal (0 V time-averaged bias, ±5 V amplitude) applied to the gate electrode. The average generated I_{sc} of 21.6 nA following voltage stress with laser illumination is ca. 25% larger than the 17.5 nA achieved with voltage stress only. TOF-SIMS measurements also demonstrate that voltage stress with laser illumination (FIGS. 23d and 23h) induces more apparent ion intensity variation than voltage stress only (FIGS. 23c and 23g). TOF-SIMS thus helps to support our hypothesis that the photon energy absorbed by the 2D perovskite layers lowers the activation energy of ion migration, greatly benefiting the formation of an asymmetric potential across the source-drain channel. By combining voltage stress and laser illumination, we demonstrate that perovskites are ideal materials for rationally tuning the ion and potential distribution with multiple stimuli to both understand and optimize electronic ratchets.

Preparation and Characterization of (PEA)₂PbI₄ Thin Films

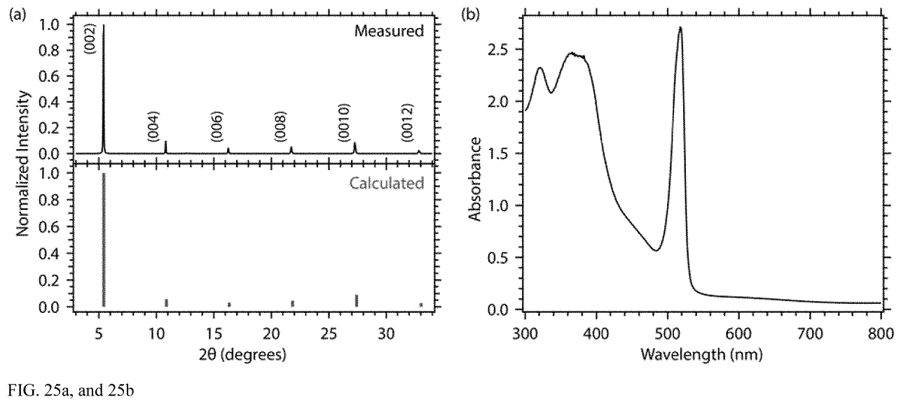

All chemicals were used as received unless otherwise indicated. Lead iodide (PbI₂, 99%) and anhydrous N,N-dimethylformamide (DMF) were purchased from Sigma-Aldrich. Phenethylammonium iodide (PEAT) was purchased from Greatcell Solar. PEAI and PbI₂ were first dissolved in DMF with a stoichiometry ratio of 2:1, forming a (PEA)₂PbI₄ solution with a concentration of 0.5 M. Thin films are then prepared by spin coating the precursor solution on to glass substrates, using a spin-rate of 4000 rpm for 30 s, followed by annealing at 100° C. for 10 min. Thin films on glass substrates are used for X-ray diffraction (θ/2θ XRD measurements of the thin film systems were taken on a Rigaku DMax 2200 diffractometer with a rotating Cu anode) and optical linear absorption measurements (Agilent Cary 5000 UV-Vis-NIR spectrophotometer), with the corresponding characterization results shown in FIGS. 25a and 25b.

Fabrication of Perovskite Electronic Ratchets

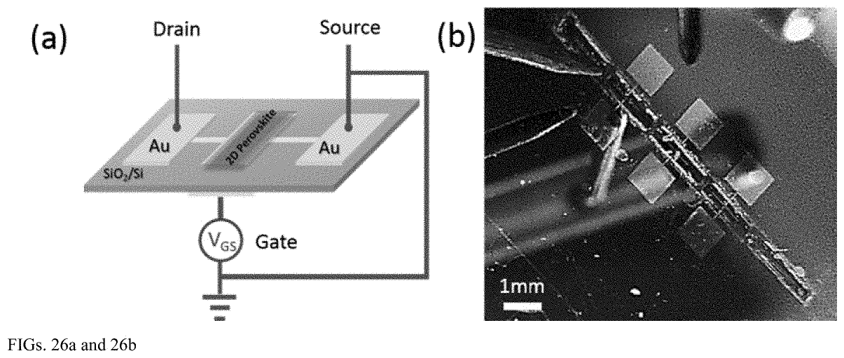

Typical devices are fabricated on field-effect transistor substrates, comprised of pre-patterned 5-nm Ti/20-nm Au electrodes on 200-nm thick SiO₂ on highly doped Si wafer with electrical resistivity of 1-10 Ω·cm. For the 2D (PEA)₂PbI₄ thin films used here, which have fairly low electrical conductivity, all measurements were performed on a device with channel lengths (L_{ch}) of ca. 3.6±0.2 μm and a channel width (W_{ch}) of 1000 μm, where the FET contact pads are fabricated through standard optical lithography. Before spin-coating the perovskite onto the FET substrate, Kapton tape was used as a mask to cover the large contact pads. The (PEA)₂PbI₄ thin films are prepared by spin coating the precursor solution onto the pre-fabricated device, using a spin-rate of 4000 rpm for 30 s, followed by annealing at 100° C. for 10 min in a nitrogen-filled glovebox. An optical microscopic image of a perovskite ratchet device is shown in FIG. 26(b).

Atomic Force and Kelvin Probe Force Microscopy (KPFM)

The surface topography and contact potential difference of the (PEA)₂PbI₄ electronic ratchet devices were measured in non-contact (tapping) mode on a Park Systems XE70 Atomic Force Microscope (AFM) using ElectriMulti75-G probes (Multi75E-G from Budget Sensors, Cr/Pt coated for electrical measurements). Topographic and potential images were measured simultaneously during the probe scanning, using a single-pass system. To remove measurement artifacts due to tilt between probe and sample planes, the raw topography images were flattened using the Park Systems XE70 Imaging software package. KPFM measures the contact potential difference between the probe and sample by nullifying the Coulomb forces experienced by the tip, which is due to the work-function difference between the probe and sample. KPFM measurements were performed at zero bias between the source and the drain electrodes of the perovskite FET, and the source contact was grounded. The line profiles in FIG. 17 were averaged from at least 25 scan lines of the topography and potential images in each scan direction.

Both before and after the voltage stress, the contact potential difference on top of the gold source and drain contacts was ca. 0.8-0.9 V. Since the source contact was held at ground (0 V) and no source-drain bias was applied to the device, the potential line profiles shown in FIG. 17a to 17d are shifted vertically so that the potential relative to the grounded source contact is illustrated.

IV and Field-effect Transistor Measurements

The typical IV measurement (FIGS. 16b and 16c) was performed by using one Keithley 2400 source meter (controlled with a laptop running a custom LabVIEW program to perform the measurement and collect experimental data) connected to the source and drain contacts. Typical field-effect transistor measurements (FIG. 16a) were performed by using two Keithley 2400 source meters (controlled with a laptop running a custom LabVIEW program to perform the measurement and collect experimental data). One Keithley 2400 source meter was used to supply the source-drain voltage and monitor the source-drain current and the other was used to supply the gate voltage and monitor the gate current.

Perovskite Electronic Ratchet Measurement System.

AC signals and electronic noise were supplied to the gate electrode of the electronic ratchet device by an Agilent 33220A signal generator and Keysight 81150A Pulse Function Arbitrary noise generator, respectively. The source-drain current of the device was monitored by Keithley 2400 source meter with Pi-filter inserted between source meter and electrodes. The waveform of the AC signal and electronic noise signal were acquired by using Tektronix Oscilloscope TBS 1152B. All the ratchet measurements were performed in a nitrogen-filled glovebox.

Lead-halide perovskites are “soft” materials, where the natural tendency for ions and vacancies to migrate with relatively low activation barriers is often problematic for electronic and optoelectronic device performance. Disclosed herein are 2D perovskite energy-harvesting electronic ratchets, where induced ion migration and redistribution are desirable processes that help to establish the asymmetry needed for ratcheting behaviour. The ability to spatially map both the potential and ion distribution in this model system allows us to directly confirm the proposed mechanism of ion migration for inducing ratchet behaviour, a correlation that has remained elusive for e.g. organic ratchets. Furthermore, the well-known sensitivity of ions to both voltage and light in perovskites allows us to improve the overall performance of perovskite ratchets through lowering the activation energy of ions. Looking forward, the broad synthetic tunability of metal halide perovskites—compositional modification of chemical components on all three lattice sites, dimensionality, chemical doping—opens up the possibility to enhance ion and charge carrier transport in these materials. These explorations, alongside additional microscopy- and spectroscopy-based characterization of the mechanisms at play, will help to demonstrate the ultimate potential of perovskite-based electronic ratchet energy harvesting devices.

The foregoing disclosure has been set forth merely to illustrate the invention and is not intended to be limiting. Since modifications of the disclosed embodiments incorporating the spirit and substance of the invention may occur to persons skilled in the art, the invention should be construed to include everything within the scope of the appended claims and equivalents thereof.

Other objects, advantages, and novel features of the present invention will become apparent from the following detailed description of the invention when considered in conjunction with the accompanying drawings.

What is claimed is:

1. An electronic ratchet device comprising a pair of first and second electrodes; a dielectric layer; a gate electrode layer; and a transport layer.

2. The electronic ratchet device of claim 1 wherein the transport layer connects the first and second electrodes, and the dielectric layer separates the transport layer and the gate electrode layer.

3. The electronic ratchet device of claim 1 wherein the first and second electrodes comprise a pair of electrodes and wherein both the first and the second electrode are fabricated from the same metal.

4. The electronic ratchet device of claim 1 wherein the first and second electrodes are fabricated from metal with dissimilar work functions.

5. The electronic ratchet device of claim 1 wherein the first and second electrodes are fabricated from metal selected from the group consisting of gold, silver, and aluminum.

6. The electronic ratchet device of claim 1 wherein the dielectric layer comprises an insulating layer with high capacitance.

7. The electronic ratchet device of claim 1 wherein the dielectric layer comprises an insulating layer selected from the group consisting of silicon dioxide, hafnium dioxide, and zirconium dioxide.

8. The electronic ratchet device of claim 1 wherein the gate electrode comprises a conductive layer.

9. The electronic ratchet device of claim 8 wherein the gate electrode comprises highly-doped silicon.

10. The electronic ratchet device of claim 1 wherein the transport layer comprises a semiconductor film.

11. The electronic ratchet device of claim 10 wherein the semiconductor film comprises a network of enriched semiconducting perovskite.

12. The electronic ratchet device of claim 11 wherein the semiconductor film comprises nanocrystal CsPbI₃.

13. The electronic ratchet device of claim 11 wherein the semiconductor film comprises 2D layered perovskite C₇H₁₀N.

14. The electronic ratchet device of claim 1 having an I_{Sc} of greater than about 2.88 mA.

15. The electronic ratchet device of claim 1 having a V_{oc} of greater than about 19 V.

16. The electronic ratchet device of claim 1 capable of generating power of greater than about 2.24×10⁻² W.

17. The electronic ratchet device of claim 1 having an I_{sc} of greater than about 2.88 mA, a V_{oc} of greater than about 19 V, and capable of generating power of greater than about 2.24×10⁻² W.

18. A method for making the electronic ratchet device of claim 1.

19. A system for generating power that uses the electronic ratchet device of claim 1.

20. A method for making power comprising exposing the electronic ratchet device of claim 1 to radiation.
